(19) United States
(12) Patent Application Publication
(10) Pub. No.: US 2007/0218701 A1
(43) Pub. Date: Sep. 20, 2007

(54) Semiconductor-processing apparatus with rotating susceptor

(75) Inventors: Akira Shimizu, Sagamihara-shi (JP); Wonyong Koh, Tokyo (JP); Hyung-Sang Park, Seoul (KR); Young-Duck Tak, Daejeon (KR)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/376,048

(22) Filed: Mar. 15, 2006

(51) Int. Cl. C23C 16/00; H01L 21/31

(52) U.S. Cl. 438/758; 118/728; 118/729; 118/730

(57) ABSTRACT

An apparatus for depositing thin film on a processing target includes: a reaction space; a susceptor movable up and down and rotatable around its center axis; and isolation walls that divide the reaction space into multiple compartments including source gas compartments and purge gas compartments, wherein when the susceptor is raised for film deposition, a small gap is created between the susceptor and the isolation walls, thereby establishing gaseous separation between the respective compartments, wherein each source gas compartment and each purge gas compartment are provided alternately in a susceptor-rotating direction of the susceptor.

### BACKGROUND OF THE INVENTION

1. Field of the Invention

The present invention generally relates to a film deposition apparatus and method for depositing thin film by atomic layer chemical vapor deposition (ALCVD), for example, on a processing target such as a semiconductor wafer.

2. Description of the Related Art

In line with the growing needs for semiconductor apparatuses capable of handling more highly integrated circuits, the ALCVD (atomic layer CVD) method, which achieves better controllability for thin film deposition than the conventional CVD (chemical vapor deposition) method, is drawing the attention. Prior technologies in this field include U.S. Pat. No. 6,572,705, U.S. Pat. No. 6,652,924, U.S. Pat. No. 6,764,546, and U.S. Pat. No. 6,645,574. In ALCVD, reactant gases A and B used for film deposition (not limited to two gases, but multiple gases such as A, B, C and D can be used and switched in accordance with the type of film to be deposited) are alternately adsorbed to the processing target and only the adsorbed layers are used to deposit film. For this reason, this method allows thin film to be deposited from several molecules in a controlled state, and stepped sections can also be coated effectively (good step coverage).

In implementing this ALCVD process, completely discharging the remaining gas from the reactor before switching from gas A to gas B, or vice versa, is important. Also, the valve tends to reach its life quickly because it must be opened/closed frequently in order to switch between source gas and purge gas. Furthermore, mass-flow control and other conventional flow control means cannot be used because of the requirement for high-speed gas switching, which inhibits on-time process monitoring. If gas remains inside the reactor, CVD reaction occurs in the vapor phase, which in turn makes it difficult to control film thickness on the molecular layer level. Also, reaction in the vapor phase generates larger grains that become unwanted particles. Traditionally, a long purge time has been required to completely discharge remaining gas A or B from the reactor, which reduces productivity.

On the other hand, a method to deposit film by placing multiple processing targets on a stage and then rotating the stage while moving it to underneath multiple showerheads has been proposed in order to improve productivity (U.S. Pat. No. 6,902,620B1). However, this method requires that the interior of showerheads that are shared by precursors A and B and thus having a lot of dead space be purged for a long period. In the patent, a similar method allowing precursors A and B to occupy separate showerheads is also proposed. In this case, however, division by means of gas curtains cannot prevent the chemical reaction between precursors A and B that are positioned side by side, and particles generate as a result. Moreover, this method requires the reaction chamber to be larger than the processing target, which means that the apparatus size must be increased if three, four or more types of precursors are used.

Another problem presented by conventional methods is the need for high-speed, repeated on/off switching of RF plasma under PEALD, where the on period must be at least one second long, or preferably two seconds, in order to stabilize plasma. Because of the matching circuit that automatically adjusts the change in chamber impedance, to meet this requirement a variable capacitor must be moved immediately after RF plasma is turned on in order to find a stable point, which presents a bottleneck in the repeated on/off process.

Additionally, methods in which an exhaust valve is attached to the showerhead have been proposed to improve the purge efficiency in dead space (e.g., U.S. Patent Publication No. 2004/0221808, No. 2005/0208217, and No. 2005/0229848, all of which are owned by the same assignee as in this application). However, in some cases, they may not provide sufficient effectiveness.

### SUMMARY OF THE INVENTION

Consequently, in an aspect, an object of the present invention is to provide an apparatus which can solve one or more of the above problems. In an embodiment, the apparatus for depositing thin film on a processing target such as a semiconductor wafer comprises: a reaction chamber; a susceptor for placing multiple processing targets thereon which is movable up and down and rotatable around its center axis; and isolation walls that divide the reaction chamber into multiple chambers (compartments) including source gas chambers and purge gas chambers, wherein when the susceptor is raised for film deposition, a small gap is created between the susceptor and the isolation walls, thereby establishing gaseous separation between the respective chambers, wherein each source gas chamber and each purge gas chamber are provided alternately in a susceptor-rotating direction of the susceptor. The susceptor on which the multiple targets are placed is rotated while continuously alternating the steps of adsorption of source gas A, purge, reaction of adsorbed source gas A with source gas B, and purge, so as to deposit thin film on each target.

In the above, each target need not stand still in the susceptor-rotating direction in each compartment while processing the target. While the target is continuously moving in the susceptor-rotating direction, the target receives designated treatment at each compartment. The rotating speed of the susceptor (i.e., the moving speed of each target in the circumferential direction of the susceptor) may be determined from the adsorption speeds and reaction speeds of precursors used as well as the required purge times. In an embodiment of ALD film deposition, the longest of the aforementioned time parameters can be used as the rotating speed. Since the ALD film deposition process is a self-saturation reaction, there is no need to stop the rotating susceptor or change the rotating speed to suit each optimal time.

In an embodiment, the susceptor temperature may be controlled in a range of about 50° C. to about 500° C., depending on the adsorption and decomposition temperatures of the types of gases used. In an embodiment, the showerhead temperature (the temperature of the compartments) may also be controlled in a range of about 50° C. to about 500° C. In an embodiment, the small gap formed between the walls and the susceptor raised during film deposition may be set in a range of about 0.5 mm to about 2 mm. In an embodiment, the apparatus is configured to introduce inactive gas from multiple gas inlets provided along the bottom of these walls and then discharge the inactive gas from exhaust ports provided in the susceptor, in order to more completely separate the respective reaction chambers. In the present invention, in an embodiment, “separation” means substantial gaseous separation which need not be complete physical separation. In another embodiment, “separation” may include pressure separation, temperature separation (when a shower plate is used), or electrical separation.

In an embodiment, multiple chambers may comprise alternately positioned source gas and purge gas chambers, so that the film deposition result will not be affected even when some source gas leaks to the adjacent chambers. Also, adsorption and/or reaction of each source gas can be separately controlled to an optimal pressure. If the source gas chambers are not provided side by side but separated by a purge gas chamber, stable control is possible even when the settings generate pressure differences among the source gas chambers.

in an embodiment, the targets themselves can also be rotated faster than the susceptor, in order to implement a CVD-like process that is not a self-saturation process.

Each wall-divided chamber need not be of the same size. Even when each chamber is smaller than the processing target, source gas adsorption and/or reaction or purge can be implemented while the processing target passes through the reaction chamber by means of susceptor rotation.

According to at least one of the embodiments described above, extra purge for switching source gases is not needed, because each source gas flows into a designated separate chamber. Since the surface of the processing target can be purged by means of susceptor rotation while the processing target passes through the purge chamber, the purge process can complete by the time the target is exposed to the next source gas. This realizes significant improvement in productivity. Furthermore, in at least one of the embodiments described above, the source gases do not mix in the vapor phase, which suppresses particle generation and improves the uniformity of film thickness. In addition, the maintenance cycles can be prolonged because only the source gas adsorbed by the susceptor causes reaction and thus unnecessary film deposition is prevented. Moreover, in at least one of the embodiments described above, high-speed gas switching is no longer necessary, which extends the valve life and enables on-time monitoring of source gas flow rates using mass-flow control for abnormality, thereby providing a stable production apparatus.

In all of the aforesaid embodiments, any element used in an embodiment can interchangeably or additionally be used in another embodiment unless such a replacement is not feasible or causes adverse effect. Further, the present invention can equally be applied to apparatuses and methods. The present invention can be applied to both apparatus and method.

For purposes of summarizing the invention and the advantages achieved over the related art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic top view of a susceptor 1 and isolation walls 3 according to an embodiment of the present invention, wherein top plates are omitted for illustrative purposes.

FIG. 2 is a schematic front view of a susceptor 1 and isolation walls 3 according to an embodiment of the present invention, wherein top plates are omitted for illustrative purposes.

FIG. 3 is a schematic segmental perspective view of an isolation wall 3 according to an embodiment of the present invention.

FIG. 4 is a schematic perspective view of a susceptor 1 and isolation walls 3 according to an embodiment of the present invention, wherein top plates are omitted for illustrative purposes.

FIG. 5 is a cross sectional view with a partially enlarged view of a susceptor 1 and isolation walls 3 according to an embodiment of the present invention, wherein top plates are omitted for illustrative purposes.

FIG. 6 is a schematic top view of a susceptor 1 and isolation walls 3 showing a position of a cross section shown in FIG. 7 according to an embodiment of the present invention, wherein top plates are omitted for illustrative purposes.

FIG. 7 is a schematic segmental cross sectional (taken along line A-B in FIG. 6) and perspective view of isolation walls 3 and a top plate 20 according to an embodiment of the present invention.

FIG. 8 is a schematic segmental cross sectional view (taken along line A-B in FIG. 6) of a susceptor 1, isolation walls 3a and 3b, a top plate 20, and an exhaust plate 30 according to an embodiment of the present invention. The drawing is not to scale.

FIG. 9 is a schematic segmental cross sectional view (taken along line A-B in FIG. 6) of a susceptor 1′, isolation walls 3c and 3d, a top plate 20′, and an exhaust plate 30′ according to an embodiment of the present invention. The drawing is not to scale.

FIG. 10 is a schematic segmental cross sectional view of the structures shown in FIG. 8, which shows the directions of gas flow 51, 52, 53, 54, and the direction of susceptor rotation 55 according to an embodiment of the present invention.

FIG. 11 is a schematic segmental cross sectional view of the structures shown in FIG. 9, which shows the directions of gas flow 52, 53, 54, 56, 57, and the direction of susceptor rotation 55 according to an embodiment of the present invention.

FIG. 12 is a schematic segmental bottom view of a top plate 20′ with a shower plate 40 (also serving as an electrode) and isolation walls 3c, 3d according to an embodiment of the present invention.

FIG. 13 is a schematic segmental top view of a susceptor 1′ with a circular exhaust port 33 and exhaust cutouts 6 according to an embodiment of the present invention.

FIG. 14 is a schematic segmental cross sectional view of the susceptor 1′ taken along line b-b shown in FIG. 13 according to an embodiment of the present invention.

FIG. 15 is a schematic segmental cross sectional view of the susceptor 1′ taken along line a-a shown in FIG. 13 according to an embodiment of the present invention.

FIG. 16 is a schematic perspective view with partial cross sections of a susceptor 101, a top plate 120, a top outer wall 121, an isolation wall 103, an exhaust plate 130, and a side outer wall 140 according to an embodiment of the present invention.

FIG. 17 is a schematic diagram showing piping of isolation walls 3a, 3b, 3c, 3d according to an embodiment of the present invention.

FIG. 18 is an imaginary schematic cross sectional view showing gas flows in an apparatus according to an embodiment of the present invention, wherein the angle (45°) between the isolation walls 3a and 3b is imaginarily expanded to 180°.

FIG. 19 is a schematic cross sectional view of the exhaust systems taken along line c-c shown in FIG. 18 according to an embodiment of the present invention.

FIG. 20 is a schematic top view of the susceptor 1 shown in FIG. 18 according to an embodiment of the present invention.

FIG. 21 is a schematic top view of the exhaust plate 30 shown in FIG. 18 according to an embodiment of the present invention.

FIG. 22 is a schematic perspective view of the exhaust plate 30 shown in FIG. 21 according to an embodiment of the present invention.

FIG. 23 is a schematic imaginary cross sectional view of an apparatus according to an embodiment of the present invention.

FIG. 24 is a schematic top view of a susceptor 1 and isolation walls 3 according to an embodiment of the present invention, wherein top plates are omitted for illustrative purposes.

FIG. 25 is a schematic top view of a susceptor 1 and isolation walls 3 according to an embodiment of the present invention, wherein top plates are omitted for illustrative purposes.

FIG. 26 is a schematic top view of a susceptor 1 and isolation walls 3 according to an embodiment of the present invention, wherein top plates are omitted for illustrative purposes.

FIG. 27 is a schematic top view of a susceptor 1 with rotating targets 2 and isolation walls 3 according to an embodiment of the present invention, wherein top plates are omitted for illustrative purposes.

FIG. 28 is a schematic cross sectional side view of the susceptor 1 with target-rotating areas 202 and the isolation walls 3 shown in FIG. 27 according to an embodiment of the present invention, wherein top plates are omitted for illustrative purposes.

### DETAILED DESCRIPTION OF THE PREFERRED EMBODIMENT

The present invention will be explained in detail with reference to preferred embodiments and drawings. However, the preferred embodiments and the drawings are not intended to limit the present invention.

The present invention can be practiced in various ways including, but not limited to, the following embodiments, wherein numerals used in the drawings are used solely for the purpose of ease in understanding of the embodiments which should not be limited to the numerals. Further, in the present specification, different terms or names may be assigned to the same element, and in that case, one of the different terms or names may functionally or structurally overlap or include the other or be used interchangeably with the other.

In an embodiment, a semiconductor-processing apparatus comprises: (i) a reaction space (e.g., 100); (ii) a susceptor (e.g., 1, 1′, 101) having multiple target-supporting areas thereon and disposed inside the reaction space for placing multiple semiconductor targets (e.g., 2) each on the target-supporting areas, said susceptor being movable between an upper position and a lower position in its axial direction and being rotatable around its axis when at the upper position; and (iii) multiple compartments (e.g., C1-C4; P1-P2 and R1-R3; P1-P4 and R1-R4; P1-P3, R1-R2, and RFA) for processing divided by partition walls (e.g., 3; 3a-3d, 103) which each extend radially from a central axis of the multiple compartments, said multiple compartments being disposed inside the reaction space over the susceptor with a gap (e.g., Δ) such that the susceptor can continuously rotate at the upper position for film deposition on the targets without contacting the partition walls, said multiple compartments being configured to operate different processes in the compartments simultaneously while the susceptor on which the targets are placed is continuously rotating at the upper position.

The above embodiment includes, but is not limited to, the following embodiments:

At least one of the partition walls may have at least one gas outflow hole (e.g., 11, 18, 40) for introducing reaction gas or purge gas (e.g., N₂, Ar, He, or Ne) into one of the multiple compartments which is defined by the at least one of the partition walls. A center of the partition walls (e.g., 4) may have a gas outflow hole (e.g., 10) for introducing purge gas or inert gas to a center of the multiple compartments. The partition walls may have gas outflow holes (e.g., 5, 12, 17, 105) for discharging inert gas toward the susceptor as a gas curtain to separate the multiple compartments with respect to gas.

At least one of the partition walls may have front and back sides (e.g., 3aF, 3bF; 3aB, 3bB) with respect to a susceptor-rotating direction, said at least one of the partition walls separating two of the multiple compartments, one of the front and back sides having at least one gas outflow hole (e.g., 11, 18) for introducing reaction gas or purge gas into one of the two multiple compartments, the other of the front and back sides having at least one gas outflow hole (e.g., 17, 12) for discharging inert gas toward the susceptor as a gas curtain to separate the one of the two multiple compartments from the other of the two multiple compartments with respect to gas. The front and back sides (e.g., 3aF and 3aB; 3bF and 3bB) of the partition wall may have planes, respectively, facing the susceptor, angled to each other, and facing away from each other.

At least one of the multiple compartments (e.g., C6) may be provided with a gas outflow port (e.g., 40) at an upper part of the at least one of the multiple compartments for introducing reaction gas or purge gas thereinto. The susceptor may have annular slits (e.g., 33) formed around the target-supporting areas for passing gas therethrough.

The susceptor may have slits (e.g., 6, 106) for passing gas therethrough each formed between the target-supporting areas. The slits may be constituted by recesses extending from a periphery of the susceptor toward a central axis of the susceptor.

The semiconductor-processing apparatus may further comprise an exhaust system (e.g., 30) having gas inflow ports (e.g., 31, 32, 37a-37d) provided under the susceptor. The exhaust system may be movable in the axial direction of the susceptor together with the susceptor without rotating around its axis.

The multiple compartments (e.g., P1-P3 v. R1-R3; P1-P4 v. R1-R4; RFA v. P1-P2/R1-R2) may have different sizes in the susceptor-rotating direction. At least one of the multiple compartments (e.g., P1-P3; P1-P4 and R1-R4; P1-P3 and R1-R2) may have a size such that each target-supporting area cannot be fully included in a region corresponding to the at least one of the multiple compartments. At least one of the multiple compartments (e.g., RFA) may be provided with an RF power supply unit or an annealing unit. At least one of the multiple compartments may be provided with a shower plate (e.g., 40) for introducing reaction gas into the at least one of the multiple compartments.

Each target-supporting area (e.g., 202) may be rotatable around its axis at a rotation speed faster than the susceptor.

In another aspect, the present invention can be applied to a method of processing semiconductor targets comprising: (a) placing multiple semiconductor targets (e.g., 2) each on target-supporting areas provide on a susceptor (e.g., 1, 1′, 101) disposed inside a reaction space (e.g., 100); (b) rotating the susceptor around its axis at an upper position where multiple compartments (e.g., C1-C4; P1-P2 and R1-R3; P1-P4 and R1-R4; P1-P3, R1-R2, and RFA) for processing divided by partition walls (e.g., 3; 3a-3d; 103) each extending radially from a central axis of the multiple compartments are disposed over the susceptor with a gap (e.g., Δ) such that the susceptor continuously rotates at the upper position for film deposition on the targets without contacting the partition walls; and (c) creating processing conditions in each compartment independently and simultaneously while the susceptor on which the targets are placed is continuously rotating at the upper position, thereby processing the targets.

The above embodiment includes, but is not limited to, the following embodiments:

The creating step may comprise introducing reaction gas or purge gas from at least one gas outflow hole (e.g., 11, 18, 40) provided in at least one of the partition walls into one of the multiple compartments which is defined by the at least one of the partition walls. The creating step may comprise introducing purge gas or inert gas from a gas outflow hole (e.g., 10) provided in a center of the partition walls (e.g., 4) to a center of the multiple compartments. The creating step may comprise discharging inert gas from gas outflow holes (e.g., 5, 12, 17, 105) provided in the partition walls toward the susceptor as a gas curtain, thereby separating the multiple compartments with respect to gas.

The creating step may comprise: (I) introducing reaction gas or purge gas from at least one gas outflow hole (e.g., 11, 18 or 12, 17) provided on either a front or a back side (e.g., 3aF, 3bF; 3aB, 3bB) provided in at least one of the partition walls into one of two of the multiple compartments divided by the at least one of the partition walls; and (II) introducing inert gas from at least one gas outflow hole (e.g., 11, 18 or 12, 17) provided on the other of the front and back sides provided in the at least one of the partition walls toward the susceptor as a gas curtain to separate the one of the two multiple compartments from the other of the two multiple compartments with respect to gas. The reaction gas or purge gas and the inert gas may be introduced in directions away from each other.

The creating step may comprise introducing reaction gas or purge gas into at least one of the multiple compartments from a gas outflow port (e.g., 40) provided in the at least one of the multiple compartments at its upper part. The creating step may further comprise passing gas through annular slits (e.g., 33) formed around the target-supporting areas of the susceptor.

The creating step may further comprise passing gas through slits (e.g., 6, 106) provided in the susceptor each formed between the target-supporting areas. The gas may be passed through the slits extending from a periphery of the susceptor toward a central axis of the susceptor.

The creating step may further comprise discharging gas from the reaction space through gas inflow ports (e.g., 31, 32; 37a-37d) provided under the susceptor. The method may further comprise moving the gas inflow ports in the axial direction of the susceptor together with the susceptor without rotating around its axis prior to the creating step.

The creating step may further comprise rotating each target-supporting area (e.g., 202) around its axis at a rotation speed faster than the susceptor.

The creating step may comprise introducing reaction gas into one of the multiple compartments (e.g., R1-R3; R1-R4; R1-R2), and introducing purge gas into another of the multiple compartments (e.g., P1-P3; P1-P4; P1-P3, respectively) adjacent to and upstream of the one of the compartments in a susceptor-rotating direction. The other of the multiple compartments (e.g., P1-P3; P1-P4 and R1-R4; P1-P3 and R1-R2) may have a size such that each target on the target-supporting area cannot be fully included in a region corresponding to the other of the multiple compartments at all times of rotating the susceptor.

The creating step may comprise applying RF power or conducting annealing of the targets in at least one of the multiple compartments (e.g., RFA).

The creating step may comprise controlling a rotating speed of the susceptor to deposit atomic layers on the targets while traveling through the multiple compartments. The creating step may further comprise constantly applying RF power in at least one of the multiple compartments while the susceptor is rotating, thereby depositing the atomic layers on the targets without a need for intermittent on/off operations of RF power.

With reference to each drawing, preferred embodiments which are not intended to limit the present invention will be explained as follows:

FIG. 1 is a schematic top view of a susceptor 1 and isolation walls 3 and FIG. 4 is a schematic perspective view of the susceptor 1 and the isolation walls 3 according to an embodiment of the present invention, wherein top plates are omitted for illustrative purposes. Four targets 2 (e.g., semiconductor substrates) are placed on respective target-supporting areas formed on the susceptor 1. The target-supporting areas have nearly or substantially the same size as or slightly larger than the targets 2, and thus are omitted from the drawings. The susceptor 1 can be configured to hold more than four targets (e.g., 5, 6, 8, 10, and numbers between any two numbers of the foregoing) or less than four targets (e.g., 2 or 3). Incidentally, all of the target-supporting areas need not be used, and fewer targets than the target-supporting areas can be held thereon, depending on the given processes.

The processing targets may be semiconductor substrates or devices and may have a diameter of 200 mm or 300 mm, although the size and shape should not be limited thereto.

In FIGS. 1 and 4, there are four compartments C1-C4 formed and divided by isolation walls 3. For example, the compartments C1 and C3 are purge gas compartments whereas the compartments C2 and C4 are reaction gas compartments wherein the purge gas compartments and the reaction gas compartments are alternately arranged, so that isolation of each compartment can be secured with respect to reaction gas because the purge gas compartments can function as buffers. The number of compartments need not be four, and independently of the number of the target-supporting areas, it can be determined depending on the given processes. FIG. 24 is a schematic top view of the susceptor 1 and isolation walls 3 according to another embodiment of the present invention. In these figures, top plates are omitted for illustrative purposes. Further, exhaust ports which may be provided in the susceptor 1 as explained below are also omitted for illustrative purposes.

In FIG. 24, there are six compartments consisting of purge gas compartments P1-P3 and reaction gas compartments R1-R3, which are alternately arranged in the susceptor-rotating direction. As in FIG. 1, at each reaction gas compartment, different reaction gas is provided. In this configuration, even if some reaction gas leaks from R1, R2, or R3 to adjacent compartments, the leaking reaction gas will not enter the other reaction gas compartments because the purge gas compartments P1-P3 function as buffer areas. As in FIG. 1, the isolation walls 3 have a center purge port 4 so as to prevent unwanted mixing of reaction gases at or near the center where manipulation of gas flows using the isolation walls is relatively difficult.

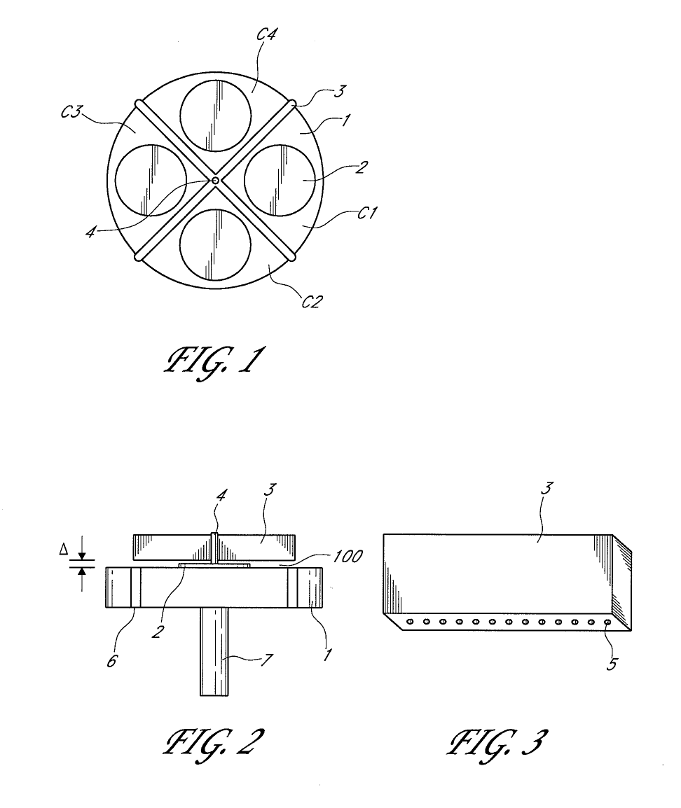

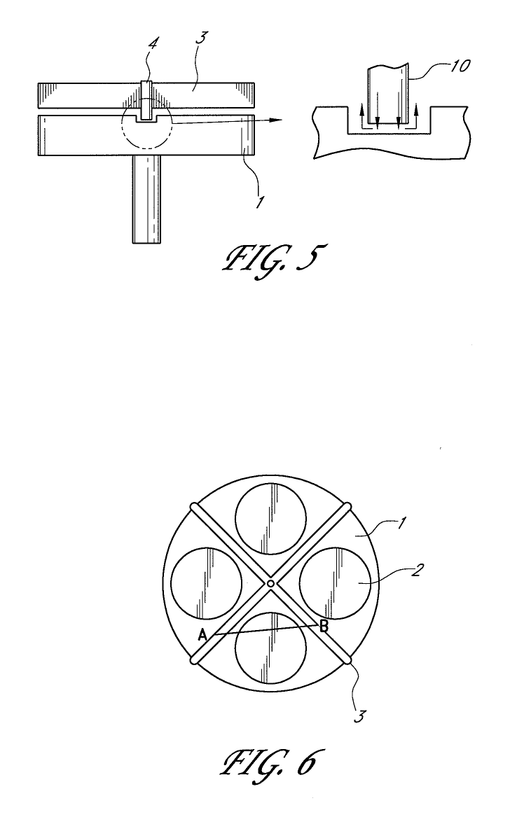

FIG. 2 is a schematic front view of the susceptor 1 and the isolation walls 3 of FIG. 1 according to an embodiment of the present invention. The center purge port 4 protrudes downward from the bottom of the isolation walls 3. FIG. 5 schematically shows a structure of the center purge port 4 in an embodiment. In this figure, the susceptor 1 has a concave portion or recess in the center (having a depth of about 2 mm to about 20 mm and a width of about 5 mm to about 40 mm, for example). The center purge port 4 may have a tubular outlet 10 having an opening at a lower end from which purge gas is discharged. The tubular outlet 10 may have a length of about 5 mm to about 40 mm. The purge gas discharged from the tubular outlet 10 flows from the center toward the periphery of the susceptor 1. This purge gas flow can effectively prevent unwanted mixing of reaction gases between the compartments.

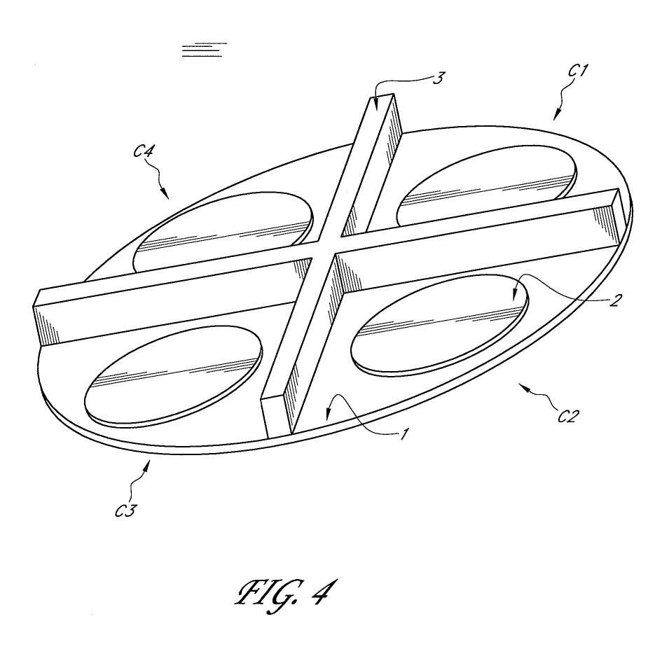

FIG. 3 is a schematic segmental perspective view of the isolation wall 3 according to an embodiment of the present invention. The isolation wall 3 has outflow holes 5 at a lower end. The outflow holes 5 are aligned from the center to the periphery. In this figure, although the outflow holes 5 are aligned in a line, other outlet holes can be aligned in a line next to the outflow holes 5, so that two different types of gas can be discharged from a front side and a back side of the isolation wall 3, respectively. Further, the angle of gas flow discharging from the outflow holes 5 can be arranged so as to discharge the gas into the designated compartment effectively. In an embodiment, reason gas is discharged at an angle toward the designated compartment, whereas purge gas is discharged straight down so as to function as a gas curtain. In the case where a purge gas compartment is provided, purge gas may be discharged at an angle toward the compartment so as to enter the compartment effectively. The isolation wall may have a width of about 5 mm to about 100 mm, preferably about 20 mm to about 40 mm (the height α+β of the isolation wall in FIG. 8 and the size of the outflow holes will be described later).

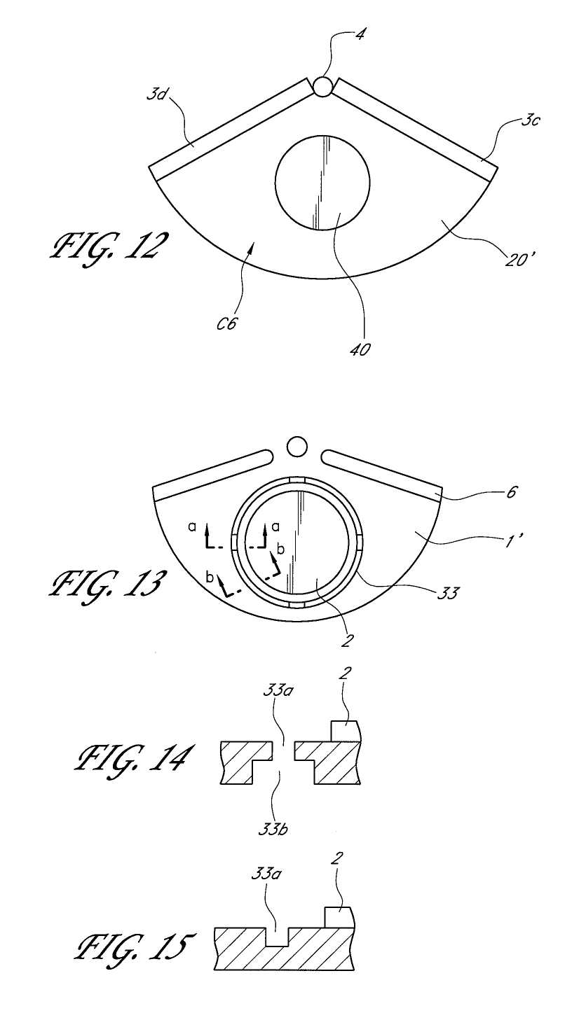

In the embodiment of FIG. 2, the susceptor 1 has exhaust cutouts 6 through which reaction gas and/or purge gas pass downward, so that contamination or unwanted mixing of reaction gas can be prevented more efficiently. The cutouts 6 may be formed between the adjacent target-supporting areas so that gas passing over one target-supporting area will be discharged through the cutouts 6 before entering the adjacent target-supporting area. In an embodiment, the cutouts 6 are extended from the periphery toward the center as shown in FIG. 13, 16, or 20. The width of the cutout 6 at the periphery may be in a range of about 5 mm to about 100 mm, and the length from the periphery toward the center may be in a range of about 100 mm to about 400 mm. The cutout 6 may be gradually narrowed toward the center or may have a constant width in a longitudinal direction. In another embodiment, the cutout 6 may be formed in multiple slits. The cutout can be formed in any shape as long as it can promote discharging gas in the compartments through the cutout. Further, in an embodiment, the cutout may have a wider opening on the top of the susceptor surface than an opening at the bottom of the susceptor. In FIG. 8 (which will be explained later), the cutout of the susceptor has a tapered surface.

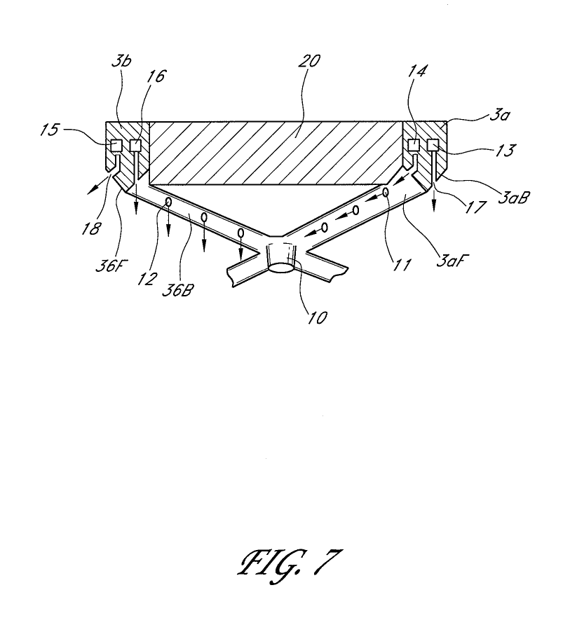

FIG. 7 is a schematic segmental cross sectional (taken along line A-B in FIG. 6) and perspective view of isolation walls 3a, 3b and a top plate 20 according to an embodiment of the present invention. In this figure, the top plate 20 is indicated. Typically, the top plate 20 is a separate piece which is connected to the isolation walls 3a, 3b. The top plate 20 may be made of aluminum, whereas the isolation walls 3a, 3b may be made of aluminum. In an embodiment, the top plate 20 can be formed integrally with the isolation walls as a single piece.

In this figure, the isolation wall 3a has a front side 3aF and a back side 3aB in the susceptor-rotating direction. The isolation wall 3b has a front side 3bF and a back side 3bB in the susceptor-rotating direction. The front side 3aF has outflow holes 11 which are angled with respect to an axial direction of the susceptor so that gas can efficiently be discharged to the compartment between the isolation walls 3a and 3b. In an embodiment, the discharging angle of gas flow from the outflow holes 11 may be about 5° to about 90° (preferably about 10° to about 85°) with respect to a plane of the top plate 20 facing the susceptor. In an embodiment, the number of the outflow holes may be 5 to 300 (preferably 10 to 200). In an embodiment, the diameter of the outflow holes may be in a range of about 0.1 mm to about 5 mm (preferably about 0.5 mm to about 2 mm). The above structural characteristics of the outflow holes may apply to the outflow holes 18 on the front side 3bF.

The outflow holes 17 and 12 on the back sides 3aB and 3bB, respectively, can have structural characteristics similar to those of the outflow holes 11, except for the discharging angle. In this figure, the outflow holes 17 and 12 are for discharging purge gas or inert gas which functions as a gas curtain, and thus, typically the discharging angle is in parallel to the axial direction of the susceptor. In an embodiment, the discharging angle of the outflow holes 17 and 12 may be arranged depending on the exhaust system provided in the apparatus. That is, gas may be discharged in a direction of the exhaust system so that the gas can efficiently and stably flow, thereby forming a good gas curtain. The number of the outflow holes for discharging purge gas or inert gas may be greater than that of the outflow holes for discharging reaction gas.

The shape of the outflow holes provided on the isolation wall need not be circular and can be oval or rectangular (such as slits). In FIG. 7, manifolds 13, 14, 15, and 16 are connected to the holes 17, 11, 18, and 12, respectively. The tubular outlet 10 at the center may be provided separately. In an embodiment, the outflow holes need not be connected to piping but may be formed in hollow isolation walls.

FIG. 16 is a schematic perspective view with partial cross sections of a susceptor 101, a top plate 120, a top outer wall 121, an isolation wall 103, an exhaust plate 130, and a side outer wall 140 according to an embodiment of the present invention. In FIG. 16, the isolation wall 103 is hollow, and the outflow holes 105 are formed in the bottom surface of the isolation wall 103. Further, a center purge port 104 is not connected to piping but is formed also in the bottom surface of the isolation wall 103. Purge gas or inert gas is introduced into the interior of the isolation wall 103 through a hole 63. Holes 61 and 64 are used for introducing purge gas or inert gas into the interior of the isolation wall 103. Hole 62 is used for introducing reaction gas into another interior of the isolation wall 103 (not shown in the figure). In that case, a wing (a portion extending from the center to its periphery) of the interior of the isolation wall 103 is divided into two longitudinal sections; one for purge gas or inert gas, the other for reaction gas.

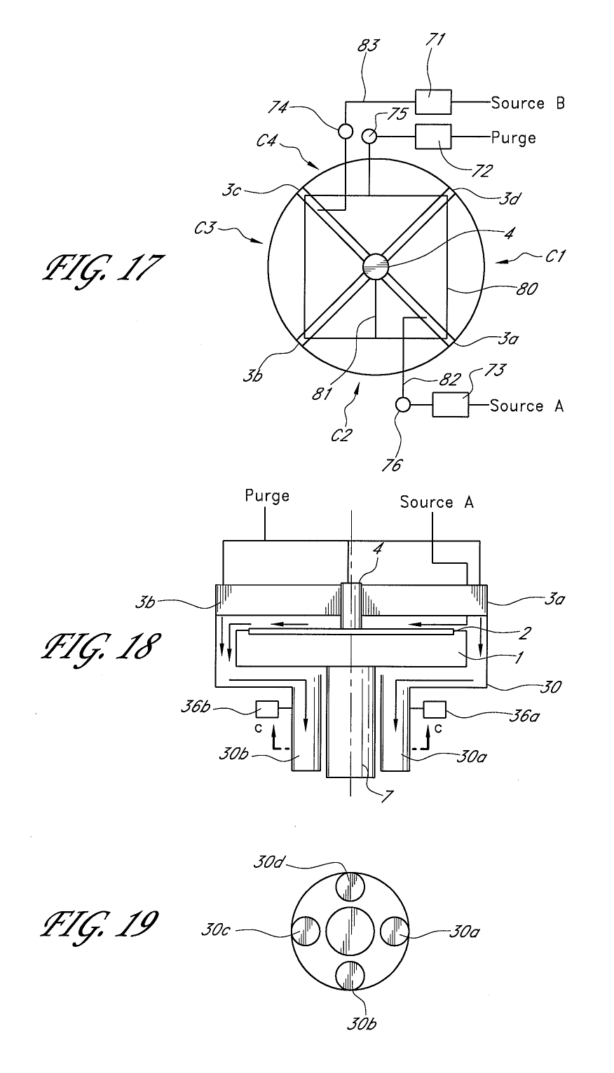

FIG. 17 is a schematic diagram showing piping of isolation walls 3a, 3b, 3c, 3d according to an embodiment of the present invention. Note that an isolation wall can be integrally formed as a single piece which has wings extending from its center to its periphery, and in that case, the wings are collectively referred to as the isolation wall. Also, an isolation wall can simply refer to each portion which divides the reaction space, and in that case, multiple isolation walls are connected to a center portion. In FIG. 17, the isolation walls 3a-3d use conduits and manifolds such as those shown in FIG. 7.

In FIG. 17, the susceptor rotates in a counter clockwise direction. Source gas A is introduced to the isolation wall 3a via a line 82 through an MFC (mass flow controller) 73 and a valve 76. Source gas A is discharged from the isolation wall 3a toward a compartment C2 at an inclined angle such as those shown in FIG. 7. That is, source gas A is introduced in a direction against the susceptor-rotating direction. Source gas B is introduced to the isolation wall 3c via a line 83 through an MFC 71 and a valve 74. Source gas B is discharged from the isolation wall 3c toward a compartment C4 at an inclined angle such as those shown in FIG. 7. Purge gas is introduced to the isolation walls 3a-3d and the center purge port 4 via lines 81, 82 through an MFC 72 and a valve 75.

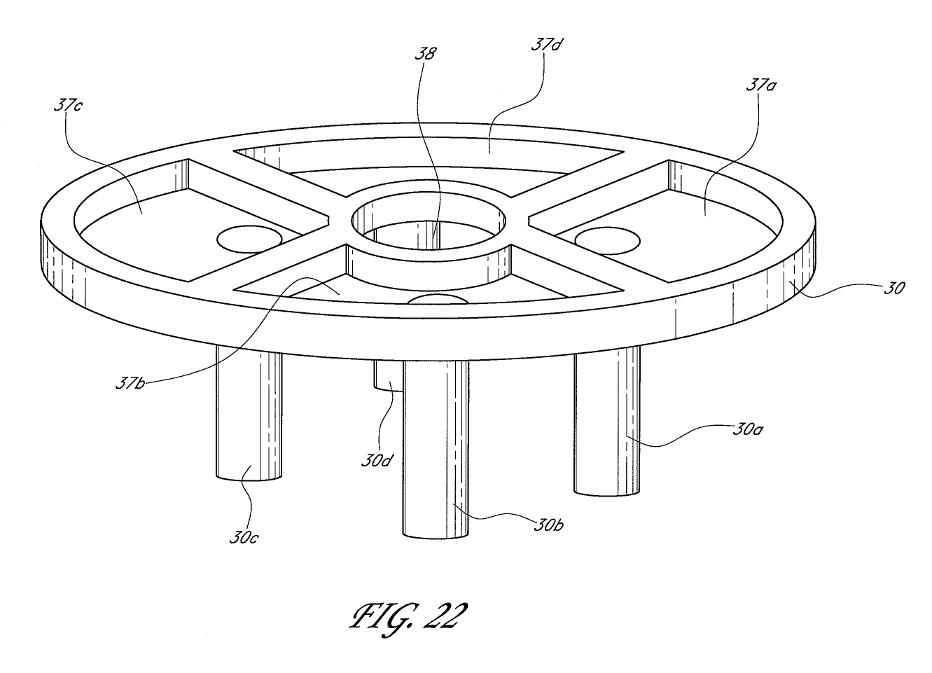

Each isolation wall has a front side and a back side (not shown) with respect to the susceptor-rotating direction. Source gas A and source gas B are discharged from the respective front sides of the isolation walls 3a and 3c. Purge gas is discharged from each back side of the isolation walls 3a, 3b, 3c, 3d straight down in the axial direction of the susceptor such as those shown in FIG. 7. Purge gas is discharged from each front side of the isolation walls 3b, 3d at an inclined angle. Purge gas is discharged from the center purge port 4 straight down. FIG. 18 is an imaginary schematic cross sectional view showing gas flows in an apparatus according to an embodiment of the present invention, wherein the angle (45°) between the isolation walls 3a and 3b is imaginarily expanded to 180°. Source gas A travels over the target 2 in a direction opposite to the susceptor-rotating direction from the isolation wall 3a while the susceptor is rotating. Source gas A is then discharged from the compartment C2 to an exhaust channel 30b through the periphery of the susceptor and an exhaust port 37b (see FIG. 21). The pressure of exhaust can be measured by a pressure sensor 36b. Purge gas from the isolation wall 3a is discharged to an exhaust channel 30a through an exhaust port 37a (see FIG. 21). The pressure of exhaust can be measured by a pressure sensor 36a.

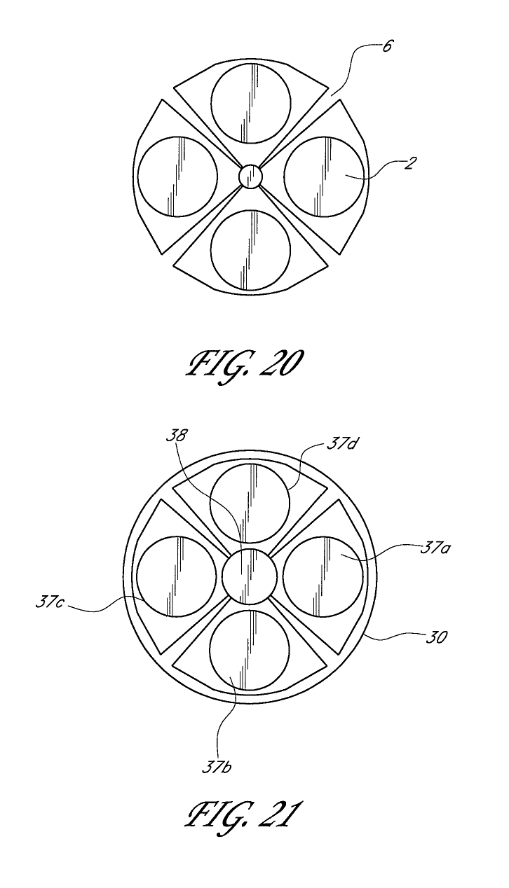

FIG. 21 is a schematic top view of the exhaust plate 30 shown in FIG. 18 according to an embodiment of the present invention. FIG. 22 is a schematic perspective view of the exhaust plate 30 shown in FIG. 21 according to an embodiment of the present invention. The exhaust plate 30 has openings 37a-37d corresponding to the compartments C1-C4. The openings are connected to exhaust channels 30a-30d, respectively (see FIG. 19). When the exhaust ports such as 37a-37d correspond to the compartment such as C1-C4, the compartments formed even with small gaps between the susceptor and the isolation walls can separately be pressure-controlled by means of a pressure-measuring means such as the pressure sensor 36a, 36b and an exhaust system. Further, the pressure of each compartment can individually be set in such a way that respective reaction gases do not mix together in the vapor phase. In the center of the exhaust plate 30, there is a through-hole 38 where a shaft 7 of the susceptor 1 is inserted.

The exhaust ports 37a-37d need not be openings shown in FIG. 21 but may be constituted by multiple slits radially extending from the center toward its periphery.

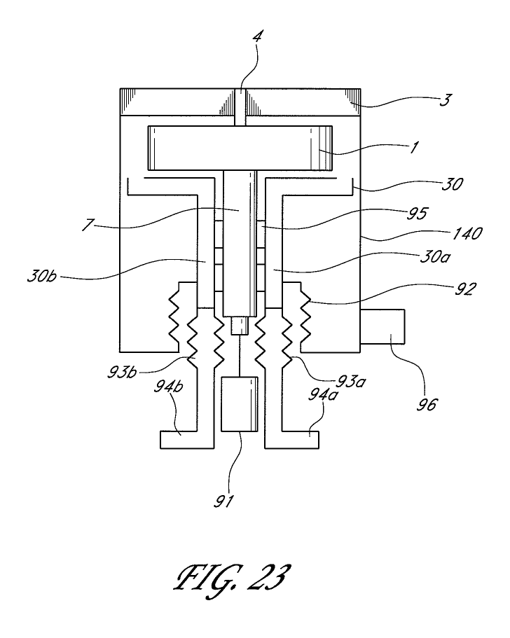

FIG. 23 is a schematic imaginary cross sectional view of an apparatus according to an embodiment of the present invention, which shows the exhaust channels 30a, 30b and the exhaust plate 30. The exhaust plate 30 is movable as is the susceptor 1. The susceptor 1 is also rotatable, but the exhaust plate 30 is not rotatable. A surbo motor 91 raises/lowers the susceptor 1 and the exhaust plate 30. The exhaust plate 30 is connected to the susceptor 1 using a magnetic seal 95 so that the exhaust plate 30 does not rotate while the susceptor 1 rotates without breaking a seal. The exhaust channels 30a, 30b are connected to exhaust pipes 94a, 94b via bellows 93a, 93b, respectively. The interior of the apparatus is connected to an exhaust 96 and sealed by bellows 92. In an embodiment, the exhaust plate is not be movable but is fixed to the apparatus, as long as steady flow of exhaust in the reaction space is efficiently established, thereby effectively isolating each compartment with respect to gas. When the susceptor and the exhaust plate are together movable, gas from the isolation wall can stably be discharged from the reaction space.

As shown in FIG. 2, in an embodiment, a distance A between a lower end of the isolation wall 3 and a top surface of the susceptor 1 is greater than a thickness of the target 2 and such that the susceptor can continuously rotate at an upper position for film deposition on the targets without contacting the partition walls and the compartments can be separated in terms of gas flows or gaseous phases. The distance A may be set at about 0.4 mm to about 5.0 mm including 0.5 mm, 1.0 mm, 1.5 mm, 2.0 mm, 3.0 mm, 4.0 mm, and ranges between any two numbers of the foregoing (preferably about 0.5 mm to about 2.0 mm). A distance between the lower end of the isolation wall 3 and a top surface of the target 2 may be in a range of about 0.1 mm to about 3.0 mm including 0.2 mm, 0.5 mm, 1.0 mm, 2.0 mm, and ranges between any two numbers of the foregoing.

FIG. 8 is a schematic segmental cross sectional view (taken along line A-B in FIG. 6) of a susceptor 1, isolation walls 3a and 3b, a top plate 20, and an exhaust plate 30 according to an embodiment of the present invention. The axis of the isolation walls is shown in a thick line 21 which is not a center purge port. The isolation walls 3a and 3b divide the reaction space 100 and sandwich the top plate 20 under which a compartment C5 is formed. The isolation wall 3a has a front side 3aF and a back side 3aB with regard to the susceptor-rotating direction. The front side 3aF of the isolation wall 3a is provided with the outflow holes 11 for reaction gas. The back side 3aB of the isolation wall 3a is provided with the outflow holes 17 for purge gas or inert gas. The isolation wall 3b has a front side 3bF and a back side 3bB with regard to the susceptor-rotating direction. The front side 3bF of the isolation wall 3b is provided with the outflow holes 18 for reaction gas. The back side 3bB of the isolation wall 3b is provided with the outflow holes 12 for purge gas or inert gas. In this embodiment, the exhaust plate 30 has exhaust ports 31, 32.

A thickness α+β of the isolation wall 3a, 3b as measured from the top surface to the lowest end may be about 10 mm to about 100 mm in an embodiment. The isolation walls 3a, 3b protrude from a lower plane of the top plate 20 by a. The difference a may be in a range of about 0.5 mm to about 5.0 mm including 1.0 mm, 1.5 mm, 2.0 mm, 3.0 mm, 4.0 mm, and ranges between any two numbers of the foregoing (preferably 1.0 mm to 2.0 mm).

FIG. 10 is a schematic segmental cross sectional view of the structures shown in FIG. 8, which shows the directions of gas flow 51, 52, 53, 54, and the direction of susceptor rotation 55 according to an embodiment of the present invention. The susceptor 1 rotates in a direction 55. Reaction gas discharged from the outflow holes 11 flows in a direction 51 which is opposite to the susceptor-rotating direction 55, wherein the reaction gas contacts the surface of the target and an ALD film is deposited on the target. This is self-saturation reaction, and thus as long as the susceptor 1 rotates at a speed such that deposition of an ALD film is complete during the target stays in the compartment C5, time control need not be precisely conducted. Purge gas or inert gas is discharged straight down from the outflow holes 17 and 12 in directions 52 and 53, respectively. The reaction gas is sucked to the exhaust port 32 of the exhaust plate 30 as shown with an arrow 54, while the purge gas is sucked to the exhaust port 31 of the exhaust plate 30 as shown with an arrow 58, thereby effectively separating the reaction gas flow and the purge gas flow. In this embodiment, the purge gas flows 52, 53 function as gas curtains, and the reaction gas flow 51 is blocked from entering the adjacent compartments. Further, the reaction gas is discharged from the compartment C5 through the cutout which is formed between the target-supporting areas, so that the reaction gas is blocked from entering the adjacent compartments.

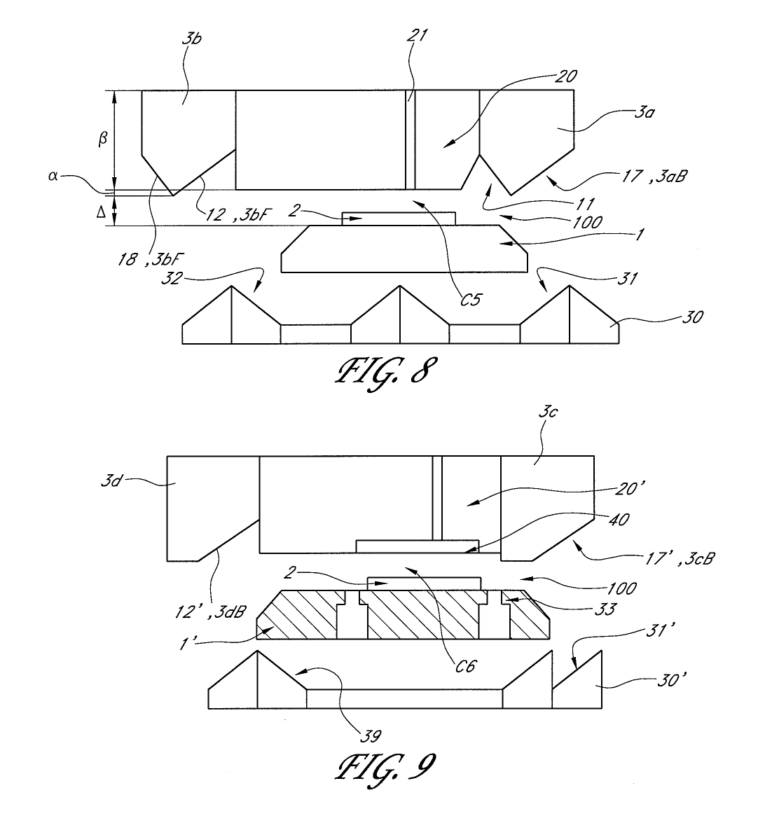

FIG. 9 is a schematic segmental cross sectional view of a susceptor 1′, isolation walls 3c and 3d, a top plate 20′, and an exhaust plate 30′ according to an embodiment of the present invention. In this embodiment, a shower plate 40 is provided at a lower surface of a top plate 20′ in a compartment C6 defined by the isolation walls 3c and 3d. Because the shower plate 40 is used to discharge reaction gas, the isolation wall 3c need not have outflow holes for discharging reaction gas. The shower plate 40 can also be used for purge gas. FIG. 12 is a schematic segmental bottom view of the top plate 20′ with the shower plate 40 and isolation walls 3c, 3d according to an embodiment of the present invention. The shower plate has multiple holes for discharging gas therethrough (not shown). The shower plate can also serve as an electrode, and the compartment C6 can be used as a plasma CVD processing chamber or annealing chamber.

The isolation wall 3c has a back side 3cB having outflow holes 17′. The isolation wall 3d has a structure similar to that of the isolation wall 3c and has a back side 3dB with outflow holes 12′. Further, in this embodiment, the susceptor 1′ has a circular exhaust port 33 (annular slits) which is formed around the target 2 to effectively create reaction gas flow (see FIGS. 13-15). Further, the exhaust plate 30 has an exhaust port 39 to collectively receive gas which has passed through the circular exhaust port 33. FIG. 13 is a schematic segmental top view of the susceptor 1′ with the exhaust port 33 and exhaust cutouts 6 according to an embodiment of the present invention. The circular exhaust port 33 is arranged in the vicinity of the periphery of the target-supporting area (which is equivalent to the target 2 to show the position of the circular exhaust port in relation thereto in the figure).

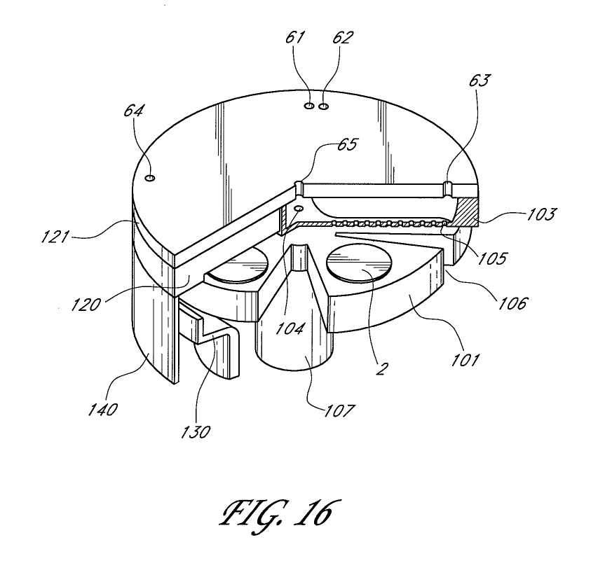

FIG. 14 is a schematic segmental cross sectional view of the susceptor 1′ taken along line b-b shown in FIG. 13 according to an embodiment of the present invention. FIG. 15 is a schematic segmental cross sectional view of the susceptor 1′ taken along line a-a shown in FIG. 13 according to an embodiment of the present invention. The circular exhaust port 33 is constituted by an upper continuous annular opening 33a on the top surface of the susceptor and lower multiple openings 33b having a width wider than (e.g., 2 to 3 times wider) that of the upper continuous annular opening 33a. The width of the upper continuous annular opening 33a may be in a range of about 1 mm to about 10 mm (preferably about 2 mm to about 5 mm). The circular exhaust port has a cross section shown in FIG. 14 which shows a step. However, the circular exhaust port need not have a step but can have a tapered surfaces having a wider opening at the lower surface of the susceptor than at the upper surface of the susceptor. In another embodiment, the circular exhaust port has no step or tapered surfaces but has a rectangular cross section. In another embodiment, the circular exhaust port has a wider opening at the top surface of the susceptor than at the bottom surface of the susceptor. By using the circular exhaust port, more stable gas flow in the compartment can be created, thereby effectively preventing mixing of gas and uniformly distributing gas over the target.

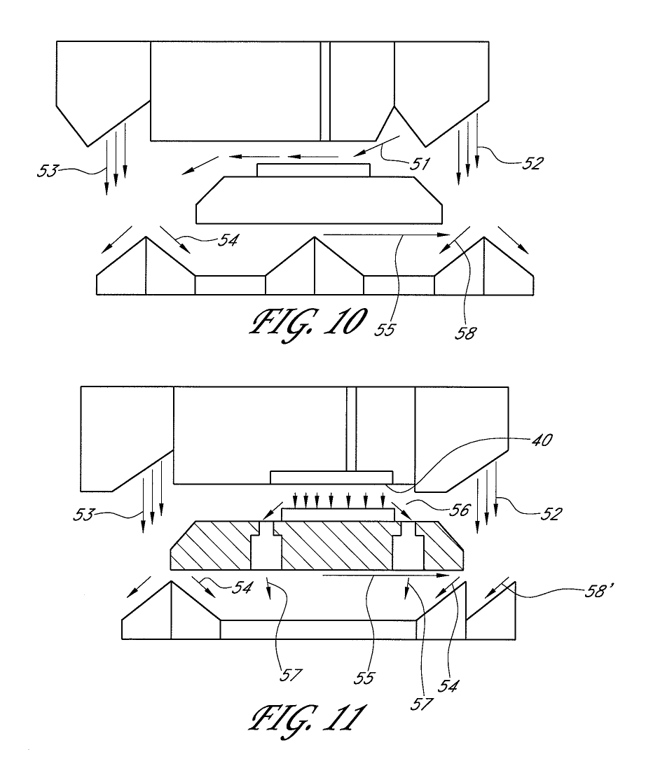

FIG. 11 is a schematic segmental cross sectional view of the structures shown in FIG. 9, which shows the directions of gas flow 52, 53, 54, 56, 57, and the direction of susceptor rotation 55 according to an embodiment of the present invention. The gas flows 52, 53 may be the same as in FIG. 10. In FIG. 11, reaction gas flows from the shower plate 40 toward the target 2 as shown with arrows 56. The reaction gas passes through the circular exhaust port 33 toward the exhaust plate 30′ as shown with arrows 57. The exhaust plate 30′ has a different shape than in FIG. 10, which has a wider opening than in FIG. 10 so that the gas which has passed through the circular exhaust port 33 can go to the common exhaust port 39. The purge gas shown with the arrow 52 is received to an exhaust port 31′ of the exhaust plate 30′ as shown with an arrow 58′. The exhaust plate can be structured as shown in FIG. 22. That is, each exhaust port 31, 32, 31′, 39 in FIGS. 8 and 9 is constituted by an opening or slit which is connected to an exhaust channel.

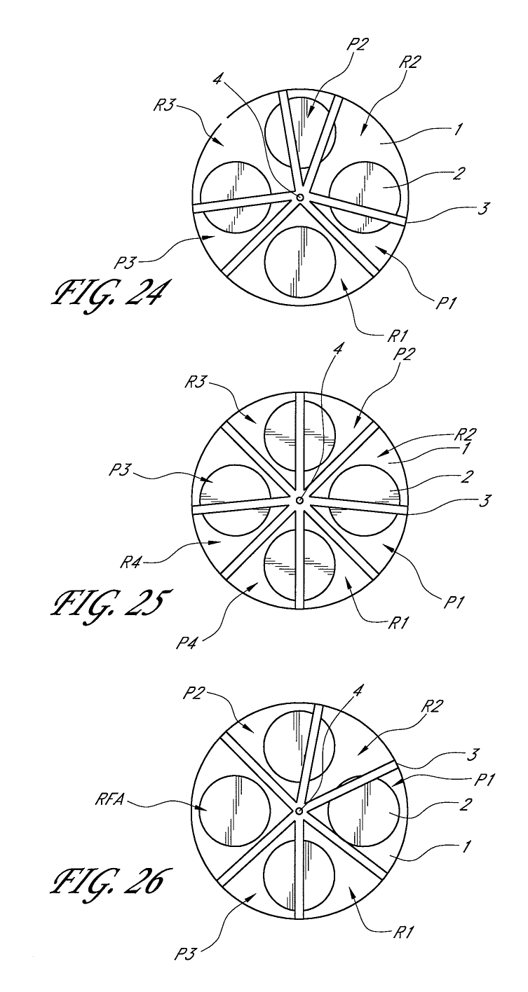

The configuration of the isolation walls can be modified as shown in FIGS. 25 and 26, for example. Each of FIGS. 25 and 26 is a schematic top view of the susceptor 1 and isolation walls 3 according to an embodiment of the present invention, wherein top plates are omitted for illustrative purposes. In both embodiments, each reaction gas compartment (R1-R4; R1-R2) is sandwiched by the purge gas compartments (P1-P4; P1-P3), so that reaction gas can be prevented from entering the other reaction gas compartments. In FIG. 26, a plasma CVD processing/annealing compartment RFA is formed. Unlike a conventional apparatus, the processing target can be passed through the compartment RFA in which RF plasma is generated continuously, in order to deposit PEALD (plasma enhanced atomic layer deposition) film without a need for intermittent on/off operations of RF. Two or more compartments can be equipped with a shower plate or an electrode. The shower plate need not serve as an electrode and be connected to an RF power source. On the other hand, an electrode can be installed in a compartment without a shower plate.

The size of each compartment can be determined based on the type of reaction (absorption speed, reaction speed, etc.), the rotation speed of the susceptor, etc. and may be such that each target-supporting area cannot be fully included in a region corresponding to the compartment. Typically, the purge gas compartments need a smaller region than the reaction gas compartments. In FIG. 24, the purge gas compartments P1-P3 are smaller than the target 2 as measured as a peripheral angle with respect to the center of the susceptor. For example, when a peripheral angle of the target-supporting area with respect to the center is 60°, a peripheral angle of the purge gas compartment P1, P2, P3 with respect to the center is less than 60°, e.g., 30-45°. In an embodiment, the peripheral angle of the purge gas compartment may be about 20% to about 90% of the peripheral angle of the target-supporting area with respect to the center (including 30%, 50%, 70%, and ranges between any two numbers of the foregoing). In another embodiment, the peripheral angle of the purge gas compartment may be about 100% to about 200% of the peripheral angle of the target-supporting area with respect to the center (including 120%, 150%, 180%, and ranges between any two numbers of the foregoing) such as shown in FIG. 1 wherein the compartments C1 and C3 are purge gas compartments whereas the compartments C2 and C4 are reaction gas compartments.

In an embodiment, the peripheral angle of the reaction gas compartment may be larger than that of the purge gas compartment, and typically about 60% to about 200% of the peripheral angle of the target-supporting area with respect to the center (including 80%, 100%, 120%, 150%, and ranges between any two numbers of the foregoing). In an embodiment, the peripheral angle of the reaction gas compartment may be larger than that of the target-supporting area.

The configurations shown in FIGS. 25 and 26 fall within the above-described ranges with respect to the size of each compartment. In FIG. 26, the compartment RFA is the largest because PEALD uses the shower plate serving as an electrode and requires uniform application of RF power to uniformly generate a plasma. For the non-plasma ALD process, because the reaction is self-saturated, the process can be applied to the target segment by segment and the reaction time is not crucial as long as the minimum reaction time is satisfied. Thus, even if the reaction gas compartment is smaller than the target as measured as a peripheral angle with respect to the center of the susceptor, the processing of the target can be effectively conducted.

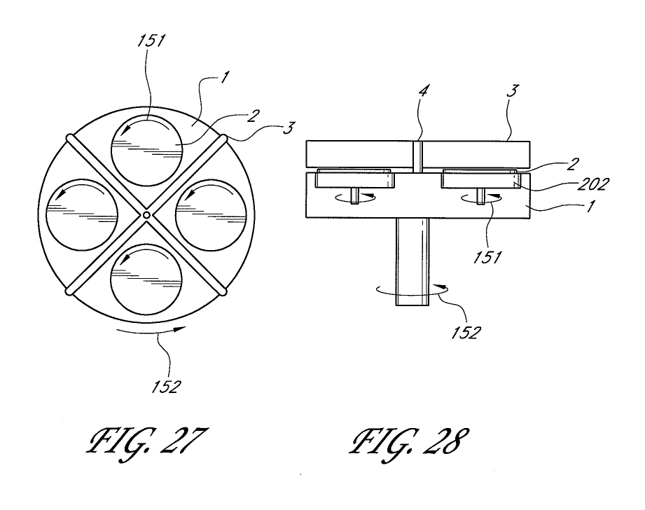

Further, in an embodiment, the target-supporting area itself can rotate. The rotation of the target-supporting area is effective when conducting non-self-saturation reaction such as plasma CVD. In that case, the size of the compartment may be larger than that of the other compartments in order to accomplish high uniformity of the process applied to the target. If the target-supporting area is rotatable, high uniformity can effectively be accomplished, even when the compartment is relatively small. In that case, preferably, the target-supporting area rotates faster than the susceptor for better uniformity. The rotation of the target-supporting area is also effective for self-saturation reaction such as ALD. FIG. 27 is a schematic top view of a susceptor 1 with a rotating targets 2 and isolation walls 3 according to an embodiment of the present invention, wherein top plates are omitted for illustrative purposes. FIG. 28 is a schematic cross sectional side view of the susceptor 1 with target-rotating areas 202 and the isolation walls 3 shown in FIG. 27 according to an embodiment of the present invention.

In an embodiment, the rotation speed of the target-supporting area may be about 5 rpm to about 400 rpm, preferably about 10 rpm to about 180 rpm. In an embodiment, the speed of the target-supporting area may be at least 1.5 times faster than that of the susceptor (including 2 times, 5 times, 10 times, and ranges between any two numbers of the foregoing). In another embodiment, the rotation speed of the target-supporting area may be lower than that of the susceptor, depending on the type of reaction. Typically, the rotation speed of the susceptor may be about 2 rpm to about 100 rpm, preferably about 5 rpm to about 60 rpm, depending on the type of reaction, the minimum deposition time, the size of the compartments, etc.

Next, in an embodiment, how thin film is deposited on a processing target is explained with reference to the drawings. This embodiment is not intended to limit the present invention. In FIG. 8, multiple semiconductor wafers 2 are placed on the susceptor 1 using a processing-target placing means (such as a vacuum robot, not shown), and the susceptor 1 and the exhaust plate 30 are raised to a reaction position using an up/down moving means (such as the surbo motor 91 in FIG. 23). At this time, the gap (A) between the susceptor 1 and the isolation wall 3 is adjusted to a specified dimension between 0.5 mm and 2 mm, for example.

A specified amount of inactive gas is then introduced from the outflow holes 17 in the isolation wall as shown in FIG. 10. Next, a specified amount of precursor A is introduced from the outflow holes 11 in the compartment C5 as shown in FIGS. 8 and 10 (which corresponds to the compartment C2 in FIG. 1). A specified amount of purge gas is introduced from the outflow holes 12 in the purge gas compartment C1 and C3 in FIG. 1, and then precursor B is introduced from the outflow holes 11 in the compartment C4 in FIG. 1. The susceptor is rotated counter clockwise in FIG. 1 at a specified speed to cause precursor A adsorbed to the processing targets to react with precursor B in order to deposit thin film. The process can begin from the reaction gas compartment C2, the purge gas compartment Cl, the reaction gas compartment C4, and the purge gas compartment C3 in sequence.

The susceptor is rotated until a specified film thickness is achieved, after which the precursor supply to the reaction gas compartments C2 and C4 and purge gas supply to the purge gas compartments C1 and C3 are stopped and the susceptor is lowered to a specified position to remove the processing targets.

Here, the reaction gas compartments C2 C4 into which precursors are introduced may be of the top flow type shown in FIGS. 9 and 11. As for the configuration shown in FIG. 9, the shower plate 40 may be replaced by a showerhead that also serves as a RF electrode, if necessary, so that RF plasma processing can be performed. Furthermore, one purge gas compartment may conform to the top flow type shown in FIG. 9 and 11, and annealing by means of RF plasma can be incorporated into the film deposition cycle corresponding to each rotation. It is also possible to make the reaction gas compartments and/or purge gas compartments smaller than the processing target, as shown in FIGS. 24 and 25.

The rotating speed of the susceptor depends on the adsorption speeds and reaction speeds of precursors as well as the required purge times, and is determined from the longest of all these times. Thickness of deposited film can be controlled by the number of times the susceptor is rotated. For example, in an Al₂O₃ (alumina) film deposition process using TMA (trimethyl aluminum) and H₂O (water) as precursors A and B, respectively, film of approx. 0.11 nm in thickness can be deposited per each susceptor rotation consisting of precursor A supply, purge, precursor B supply, and purge. Therefore, the precursor needs to be rotated 36 times to deposit film of 4 nm in thickness.

In this case, the reaction space is divided into four sections and the period of H₂O purge that requires the longest time is set to 750 msec. This translates to 20 rpm in susceptor speed, at which four semiconductor wafers can be processed during the film deposition time of 1.8 minutes. As a result, the throughput becomes 133 wafers per hour. Under conventional methods, the throughput is around 40 wafers per hour because an extra purge time is needed to switch the precursor in the reactor. In this embodiment of the present patent application, four processing targets are placed on the susceptor. If the number of compartments is simply increased to four under any conventional method, such configuration can achieve an equivalent throughput. However, each compartment needs a separate gas line and exhaust pump, as well as a separate RF circuit if RF is used, and thus the apparatus cost increases. Also, the maintenance cycle becomes shorter with such conventional structure due to the reaction of precursors A and B adsorbed to the showerhead. Furthermore, the number of processing targets that can be placed on the susceptor is not limited to four under the present patent application. The rotating speed of the susceptor is not limited to 20 rpm, either, and the susceptor speed can be raised further if precursors A and B used have higher adsorption speeds and reaction speeds. This allows for further improvement in throughput. As shown in the additional drawing, it is also possible to rotate the wafer at a speed faster than the susceptor in order to implement a CVD-like process that is not a saturation process.

Use of the proposed method improves productivity significantly, because the respective precursors are introduced only into the dedicated reaction chambers (compartments) and thus there is no need for the extra purge for precursor switching that has been a main cause of reduced productivity, process instability and lower repeatability under conventional processes. Also, the alternate placement of reaction gas and purge gas compartments prevents the precursors from mixing together in the vapor phase, which suppresses particle generation and prevents film from depositing in unnecessary areas, consequently leading to a longer maintenance cycle. In addition, the precursors can be introduced continuously, which extends the valve life and permits process monitoring using a mass-flow controller, etc. As a result, on-time monitoring of material supply volumes for abnormality, etc., becomes possible. U.S. Patent Publication No. 2004/0221808, No. 2005/0208217, and No. 2005/0229848, all of which are owned by the same assignee as in this application, describe ALD processes and the disclosure of the above is herein incorporated by reference in their entirety.

### EXAMPLE 1

Shown below are the film deposition results of the method according to an embodiment of the present invention and a conventional method, in an example of WNC (tungsten nitride carbide) film deposition using TEB (triethyle boron), WF₆ (tungsten hexafluoride), NH₃ (ammonia) as precursors, and Ar as purge gas or inert gas. For the embodiment of the present invention, an apparatus shown in FIGS. 8, 17, and 24 were used wherein:

The gap Δ: 1.2 mm

The height α+β of the isolation wall: 51.5 mm

The thickness β of the top plate: 50 mm

The width of the cutout: 10 mm

The peripheral angle of the purge gas compartment: 20°

The peripheral angle of the reaction gas compartment: 30°

The number of outflow holes for purge gas and reaction gas: 50

The diameter of the wafer: 300 mm

The flow of purge gas from the center: 20 sccm

The flow of purge gas to the compartments: 1000 sccm

The flow of precursor TEB: 400 sccm with carrier N₂ gas

The flow of precursor WF₆: 15 sccm

The flow of precursor NH₃: 400 sccm

The pressure of the compartments P1-P3: 200 Pa

The pressure of the compartments R1: 300 Pa

The pressure of the compartments R2: 150 Pa

The pressure of the compartments R3: 150 Pa

The temperature of the reaction chamber (deposition temperature): 320° C.

Comparative method (U.S. Patent Publication No. 2004/0221808, No. 2005/0208217, and No. 2005/0229848): showerhead type, with showerhead exhaust

Deposition was conducted under the conditions shown in Table 1.

TABLE 1

| | TEB | | WF₆ | | NH₃ | | Cycle time | Throughput* |
|---|---|---|---|---|---|---|---|---|
| Conventional | Pulse | Purge | Pulse | Purge | Pulse | Purge | 6.5 | 11 wafers/hour |
| method | 1 sec | 1.5 sec | 0.5 sec | 1 sec | 0.5 sec | 2 sec | | |

| | | | |
|---|---|---|---|
| Present patent | 20 rpm | 3 | 96 wafers/hour |
| application | | | |

*Deposition speed: 0.08 nm/cycle (film thickness: 4 nm)

Comparison of film deposition results (WNC, 25 nm) is shown in Table 2.

TABLE 2

| | Thickness | Rs | Rs | Resistivity | Particle |
|---|---|---|---|---|---|
| | nm | Ω/□ | 1σ % | μΩ cm | increase* |
| Conventional | 25.4 | 152 | 2.2 | 386.0 | 52 |
| method | | | | | |
| Example 1 | 25.1 | 145 | 0.5 | 363.9 | 8 |

*Particle: 0.16 μm or more

As shown in Table 2, in Example 1, particle contamination in the film was significantly inhibited because mixing of the precursors was effectively inhibited by sandwiching each reaction gas compartment between the purge gas compartments using continuous flows of purge gas and precursor gases. Further, uniformity of the film characteristics was very high in Example 1. Furthermore, the throughput was about nine times higher in Example 1 than in the conventional method.

### EXAMPLE 2

Explained below is an example of Ru film deposition by PEALD (plasma enhance ALD) according to an embodiment of the present invention. For this embodiment of the present invention, simulation was conducted to calculate a throughput assuming that an apparatus shown in FIGS. 9, 13, and 26 are used wherein conditions not specified below are the same as in Example 1:

The peripheral angle of the purge gas compartment: 15°

The peripheral angle of the reaction gas compartment: 20°

The peripheral angle of the RFA compartment: 90°

RF power: 200 W, 13.56 MHz

The flow of purge gas from the center: 20 sccm

The flow of purge gas to the compartments: 1000 sccm

The flow of precursor Ru: 400 sccm with He carrier gas

The flow of precursor NH₃: 400 sccm

The pressure of the compartments P1-P2: 200 Pa

The pressure of the compartments R1: 400 Pa

The pressure of the compartment RFA: 150 Pa

The temperature of the reaction chamber (deposition temperature): 320° C.

Comparative method (U.S. Patent Publication No. 2004/0221808, No. 2005/0208217, and No. 2005/0229848): showerhead type, with showerhead exhaust

Deposition was simulated under the conditions shown in Table 3.

TABLE 3

| | Ru* | | NH₃ | RF | | Cycle time | Throughput* |
|---|---|---|---|---|---|---|---|
| Conventional | Pulse | Purge | Flow | On | Purge | 7 | 5 wafers/hour |
| method | 1 sec | 1.5 sec | 0.5 sec | 2 sec | 2 sec | | |

| | | | |
|---|---|---|---|
| Example 2 | 20 rpm | 3 | 48 wafers/hour |

*Growth speed: 0.02 nm/cycle (film thickness: 2 nm)

As a result, the simulation reveals that the throughput is about ten times higher in Example 2 than in the conventional method.

The present invention includes the above mentioned embodiments and other various embodiments including the following:

1) An apparatus for depositing thin film on a semiconductor wafer being a processing target, comprising: a reaction chamber, a susceptor on which multiple processing targets are placed, and a raising/lowering means for moving the susceptor up and down; a rotating means for rotating the susceptor around the center axis; and walls that divide the reactor into multiple chambers; the apparatus characterized in that, when depositing film, the susceptor is raised to create small gaps along the walls and thereby separating the respective reaction chambers, source gas and purge gas chambers are provided alternately, and the susceptor means on which the processing targets are placed is rotated to deposit thin film on the processing targets.

2) An apparatus described in 1), characterized in that, when depositing film, the susceptor is raised and inactive gas is introduced into the small gaps formed along the walls separating the reaction chamber into multiple chambers, and then the inactive gas is discharged from exhaust ports provided in positions directly facing the wall provided on the susceptor means, in order to separate the respective chambers.

3) An apparatus described in 2), characterized in that the inactive gas is either N₂, Ar, He or Ne.

4) An apparatus described in 1), characterized in that source gas or purge gas is introduced from the outlet-side wall in the rotating direction of the susceptor and discharged from the inlet side.

5) An apparatus described in 1), characterized in that source gas or purge gas is introduced from above the space divided by the walls, and discharged from an exhaust port provided on the outer periphery of each processing target on the susceptor.

6) An apparatus described in 1), characterized in that source gas is adsorbed and/or reacted or purged while the processing target passes by means of susceptor rotation through a wall-divided chamber smaller than the processing target.

7) An apparatus described in 1), characterized in that the susceptor rotates continuously.

8) An apparatus described in 1), characterized in that RF plasma is applied to one or more wall-divided chambers in order to deposit film or provide annealing effect.

9) An apparatus described in 1), characterized in that the chambers formed by the small gaps between the susceptor and walls are separately pressure-controlled by means of a pressure-measuring means and a pressure-controlling means.

10) An apparatus described in 9), characterized in that the pressure of each chamber is set in such a way that respective source gases do not mix together in the vapor phase.

11) An apparatus described in 1), characterized in that the processing target is passed by means of susceptor rotation through a RF plasma chamber in which RF plasma is generated continuously, in order to deposit PEALD film without a need for intermittent on/off operations of RF.

12) An apparatus described in 1), characterized in that film is deposited with the processing target rotated at a speed faster than the rotating speed of the susceptor.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. An apparatus for deposition thin film on a target, comprising:
a reaction space;
a susceptor having multiple target-supporting areas thereon and disposed inside the reaction space for placing multiple targets each on the target-supporting areas, said susceptor being movable between an upper position and a lower position in its axial direction and being rotatable around its axis when at the upper position; and
multiple compartments for processing divided by partition walls which each extend radially from a central axis of the multiple compartments, said multiple compartments being disposed inside the reaction space over the susceptor with a gap such that the susceptor can continuously rotate at the upper position for film deposition on the targets without contacting the partition walls, said multiple compartments being configured to operate different processes in the compartments simultaneously while the susceptor on which the targets are placed is rotating at the upper position.

2. The apparatus according to claim 1, wherein at least one of the partition walls has at least one gas outflow hole for introducing reaction gas or purge gas into one of the multiple compartments which is defined by the at least one of the partition walls.

3. The apparatus according to claim 1, wherein a center of the partition walls has a gas outflow hole for introducing purge gas or inert gas to a center of the multiple compartments.

4. The apparatus according to claim 1, wherein the partition walls have gas outflow holes for discharging inert gas toward the susceptor as a gas curtain to separate the multiple compartments with respect to gas.

5. The apparatus according to claim 1, wherein at least one of the partition walls has front and back sides with respect to a susceptor-rotating direction, said at least one of the partition walls separating two of the multiple compartments, one of the front and back sides having at least one gas outflow hole for introducing reaction gas or purge gas into one of the two multiple compartments, the other of the front and back sides having at least one gas outflow hole for discharging inert gas toward the susceptor as a gas curtain to separate the one of the two multiple compartments from the other of the two multiple compartments with respect to gas.

6. The apparatus according to claim 5, wherein the front and back sides of the partition wall have planes, respectively, facing the susceptor, angled to each other, and facing away from each other.

7. The apparatus according to claim 1, wherein at least one of the multiple compartments is provided with a gas outflow port at an upper part of the at least one of the multiple compartments for introducing reaction gas or purge gas thereinto.

8. The apparatus according to claim 7, wherein the susceptor has annular slits formed around the target-supporting areas for passing gas therethrough.

9. The apparatus according to claim 1, wherein the susceptor has slits for passing gas therethrough each formed between the target-supporting areas.

10. The apparatus according to claim 9, wherein the slits are constituted by recesses extending from a periphery of the susceptor toward a central axis of the susceptor.

11. The apparatus according to claim 1, further comprising an exhaust system having gas inflow ports provided under the susceptor.

12. The apparatus according to claim 11, wherein the exhaust system is movable in the axial direction of the susceptor together with the susceptor without rotating around its axis.

13. The apparatus according to claim 1, wherein the multiple compartments have different sizes in a susceptor-rotating direction.

14. The apparatus according to claim 1, wherein each target-supporting area is rotatable around its axis at a rotation speed faster than the susceptor.

15. The apparatus according to claim 1, wherein at least one of the multiple compartments has a size such that each target-supporting area cannot be fully included in a region corresponding to the at least one of the multiple compartments.

16. The apparatus according to claim 1, wherein at least one of the multiple compartments is provided with an RF power supply unit or an annealing unit.

17. The apparatus according to claim 1, wherein at least one of the multiple compartments is provided with a shower plate for introducing reaction gas into the at least one of the multiple compartments.

18. An apparatus for depositing thin film on a processing target, comprising:
a reaction space;
a susceptor for placing multiple processing targets thereon, said susceptor being movable up and down and rotatable around its center axis; and
isolation walls that divide the reaction space into multiple compartments including source gas compartments and purge gas compartments, wherein when the susceptor is raised for film deposition, a small gap is created between the susceptor and the isolation walls, thereby establishing gaseous separation between the respective compartments, wherein each source gas compartment and each purge gas compartment are provided alternately in a susceptor-rotating direction of the susceptor.

19. The apparatus according to claim 18, wherein the small gap is about 0.5 mm to about 2.0 mm.

20. A method of processing semiconductor targets, comprising:
placing multiple semiconductor targets each on target-supporting areas provide on a susceptor disposed inside a reaction space;
rotating the susceptor around its axis at an upper position where multiple compartments for processing divided by partition walls each extending radially from a central axis of the multiple compartments are disposed over the susceptor with a gap such that the susceptor continuously rotates at the upper position for film deposition on the targets without contacting the partition walls; and
creating processing conditions in each compartment independently and simultaneously while the susceptor on which the targets are placed is continuously rotating at the upper position, thereby processing the targets.

21. The method according to claim 20, wherein the creating step comprises introducing reaction gas or purge gas from at least one gas outflow hole provided in at least one of the partition walls into one of the multiple compartments which is defined by the at least one of the partition walls.

22. The method according to claim 21, wherein the creating step comprises introducing purge gas or inert gas from a gas outflow hole provided in a center of the partition walls to a center of the multiple compartments.

23. The method according to claim 20, wherein the creating step comprises discharging inert gas from gas outflow holes provided in the partition walls toward the susceptor as a gas curtain, thereby separating the multiple compartments with respect to gas.

24. The method according to claim 20, wherein the creating step comprises:
introducing reaction gas or purge gas from at least one gas outflow hole provided on either a front or a back side provided in at least one of the partition walls into one of two of the multiple compartments divided by the at least one of the partition walls; and
introducing inert gas from at least one gas outflow hole provided on the other of the front and back sides provided in the at least one of the partition walls toward the susceptor as a gas curtain to separate the one of the two multiple compartments from the other of the two multiple compartments with respect to gas.

25. The method according to claim 24, wherein the reaction gas or purge gas and the inert gas are introduced in directions away from each other.

26. The method according to claim 20, wherein the creating step comprises introducing reaction gas or purge gas into at least one of the multiple compartments from a gas outflow port provided in the at least one of the multiple compartments at its upper part.

27. The method according to claim 26, wherein the creating step further comprises passing gas through annular slits formed around the target-supporting areas of the susceptor.

28. The method according to claim 20, wherein the creating step further comprises passing gas through slits provided in the susceptor each formed between the target-supporting areas.

29. The method according to claim 28, wherein the gas is passed through the slits extending from a periphery of the susceptor toward a central axis of the susceptor.

30. The method according to claim 20, wherein the creating step further comprises discharging gas from the reaction space through gas inflow ports provided under the susceptor.

31. The method according to claim 30 further comprising moving the gas inflow ports in the axial direction of the susceptor together with the susceptor without rotating around its axis prior to the creating step.

32. The method according to claim 20, wherein the creating step further comprises rotating each target-supporting area around its axis at a rotation speed faster than the susceptor.

33. The method according to claim 20, wherein the creating step comprises introducing reaction gas into one of the multiple compartments, and introducing purge gas into another of the multiple compartments adjacent to and upstream of the one of the compartments in a susceptor-rotating direction.

34. The method according to claim 33, wherein the other of the multiple compartments has a size such that each target on the target-supporting area cannot be fully included in a region corresponding to the other of the multiple compartments at all times of rotating the susceptor.

35. The method according to claim 20, wherein the creating step comprises applying RF power or conducting annealing of the targets in at least one of the multiple compartments.

36. The method according to claim 20, wherein the creating step comprises controlling a rotating speed of the susceptor to deposit atomic layers on the targets while traveling through the multiple compartments.

37. The method according to claim 36, wherein the creating step further comprises constantly applying RF power in at least one of the multiple compartments while the susceptor is rotating, thereby depositing the atomic layers on the targets without a need for intermittent on/off operations of RF power.
